(19) United States
(12) Patent Application Publication
(10) Pub. No.: US 2010/0289056 A1
(43) Pub. Date: Nov. 18, 2010

(54) SEMICONDUCTOR LIGHT-EMITTING DEVICES

(75) Inventors: Akihito Ohno, Tokyo (JP); Masayoshi Takemi, Tokyo (JP); Nobuyuki Tomita, Tokyo (JP)

Correspondence Address: LEYDIG VOIT & MAYER, LTD, 700 THIRTEENTH ST. NW, SUITE 300, WASHINGTON, DC, 20005-3960, US

(73) Assignee: MITSUBISHI ELECTRIC CORPORATION, Tokyo (JP)

(21) Appl. No.: 12/835,772

(22) Filed: Jul. 14, 2010

Related U.S. Application Data
(62) Division of application No. 11/854,647, filed on Sep. 13, 2007.

(30) Foreign Application Priority Data
Sep. 27, 2006 (JP) 2006-262845
Aug. 23, 2007 (JP) 2007-217511

(51) Int. Cl. H01L 33/12

(52) U.S. Cl. 257/101; 257/E33.043

(57) ABSTRACT

A semiconductor laser device comprises an n-type cladding layer, a p-type cladding layer, and an active layer which is sandwiched between the n-type cladding layer and the p-type cladding layer. The p-type cladding layer contains magnesium as a dopant impurity. Further, an n-type diffusion blocking layer of a nitride compound semiconductor material located between the active layer and the p-type cladding layer and is InₓAl_{y}Ga_{1-x-y}N, where x≧0, y≧0, and (x+y)<1. The n-type diffusion blocking layer preferably has a concentration of a dopant impurity producing n-type conductivity in a range from 5×10¹⁷ cm⁻³ to 5×10¹⁹ cm⁻³.

### BACKGROUND OF THE INVENTION

1. Field of the Invention

The present invention relates to semiconductor light-emitting devices such as semiconductor lasers and light-emitting diodes using a nitride compound semiconductor.

2. Background Art

In recent years, considerable research effort has been expended to use Group III-V nitride compound semiconductors as materials for light-emitting devices and electronic devices. Having favorable characteristics, Group III-V nitride compound semiconductors have been already put to practical use as materials for blue and green light-emitting diodes and for blue-violet semiconductor lasers, which are light sources for next-generation high density optical disks.

Conventional semiconductor lasers are disclosed in, for example, Japanese Patent Specification No. 2780691 (hereinafter referred to as “Patent Document 1”) and Japanese Patent Laid-Open No. 2002-261395 (hereinafter referred to as “Patent Document 2”).

Specifically, Patent Document 1 discloses a nitride semiconductor light-emitting device that includes: an active layer having first and second surfaces and made of a nitride semiconductor material containing indium (In) and gallium (Ga); an n-type nitride semiconductor layer of InₓGa₁₋ₓN (0≦x<1) in contact with the first surface of the active layer; and a p-type nitride semiconductor layer of Al_{y}Ga_{1-y}N (0<y<1) in contact with the second surface of the active layer.

Patent Document 2, on the other hand, discloses a semiconductor light-emitting device that includes: an active layer made of a first Group III-V nitride compound semiconductor material containing indium and gallium; an intermediate layer in contact with the active layer and made of a second or different Group III-V nitride compound semiconductor material containing indium and gallium; and a capping layer in contact with the intermediate layer and made of a third Group III-V nitride compound semiconductor material containing aluminum (Al) and gallium.

However, the semiconductor laser disclosed in Patent Document 1 is disadvantageous in that the initial degradation rate of the laser is high when it is operated or when power is applied to it, and furthermore the operating current gradually increases with time. These problems prevent the semiconductor laser from having an extended life and result in a significant reduction in the yield.

On the other hand, Patent Document 2 proposes that a Group III-V nitride compound semiconductor layer containing indium and gallium, that is, formed of InGaN, etc. be inserted between the active layer and the capping layer as described above. However, this structure alone cannot provide sufficient life extension. Furthermore, the problem of degradation in the light emission characteristics and in reliability still remains to be solved.

### SUMMARY OF THE INVENTION

The present invention has been devised in view of the above problems. It is, therefore, an object of the present invention to provide a semiconductor light-emitting device having a low initial degradation rate and an extended life.

According to one aspect of the present invention, a semiconductor light-emitting device comprises an n-type cladding layer of a nitride compound semiconductor material, an active layer of a nitride compound semiconductor material on the n-type cladding layer, and a p-type cladding layer of a nitride compound semiconductor material on the active layer. The p-type cladding layer contains magnesium as impurities. An n-type diffusion blocking layer of a nitride compound semiconductor material is provided between the active layer and the p-type cladding layer. The nitride compound semiconductor material is represented by the following formula.

InₓAl_{y}Ga_{1-x-y}N(x≧0, y≧0, (x+y)<1)

Other objects and advantages of the present invention will become apparent from the following description.

### BRIEF DESCRIPTION OF THE DRAWINGS

FIG. 1 is a cross-sectional view of a semiconductor laser device according to a first embodiment of the present invention;

FIG. 2 is a diagram showing results of testing the operation of the semiconductor laser device of the first embodiment;

FIG. 3 is a diagram showing results of testing the operation of the semiconductor laser device of the first embodiment, in which the doping concentration of the impurity in the n-type diffusion blocking layer was varied;

FIG. 4 is a diagram showing results of testing the operation of the semiconductor laser device of the first embodiment, in which the thickness of the n-type diffusion blocking layer was varied;

FIG. 5 is a cross-sectional view of another semiconductor laser device according to the first embodiment;

FIG. 6 is a cross-sectional view of still another semiconductor laser device according to the first embodiment; and

FIG. 7 is a cross-sectional view of a semiconductor laser device according to a second embodiment of the present invention.

FIG. 8 shows the concentration profiles of magnesium, hydrogen, and silicon in the semiconductor laser device of the present embodiment as a function of depth.

### DETAILED DESCRIPTION OF THE PREFERRED EMBODIMENTS

Nitride compound semiconductor light-emitting devices exhibit a high initial degradation rate when they are operated. One reason for this is that magnesium, a dopant in the p-type semiconductor layer, diffuses into the active layer when the devices are in operation. On the other hand, when a manufacturing process for a nitride semiconductor light-emitting device uses a hydrogen-containing compound as a material, hydrogen remains within the semiconductor layers. The present inventors believed that diffusion of this hydrogen to the active layer may be another reason for the high initial degradation rate of nitride compound semiconductor light-emitting devices, which has led to the present invention.

As described above, the p-type semiconductor layers contain magnesium as a dopant. Further, since hydrogen combines with magnesium, the p-type semiconductor layers contain more hydrogen than the n-type semiconductor layers. This means that the high initial degradation rate of nitride compound semiconductor light-emitting devices is attributed to diffusion of both hydrogen and magnesium from the p-type semiconductor layer to the active layer.

The present invention is directed to overcoming this problem. According to the present invention, an n-type diffusion blocking layer made of a compound represented by formula (1) below is provided between the active layer and a p-type semiconductor layer, namely, the p-type cladding layer. Examples of n-type impurities that may be doped in the n-type diffusion blocking layer include silicon (Si), selenium (Se), and sulfur (S).

InₓAl_{y}Ga_{1-x-y}N(x≧0, y≧0, and (x+y)<1) (1)

In a nitride compound semiconductor light-emitting device of the present invention, the n-type diffusion blocking layer may be made up of a single layer, or it may be made up of a plurality of layers. In the former case, the doping concentration of the n-type impurity in the n-type diffusion blocking layer is preferably between 5×10¹⁷ cm⁻³ and 5×10¹⁹ cm⁻³. In the latter case, at least one layer in the n-type diffusion blocking layer must contain an n-type impurity.

The n-type diffusion blocking layer prevents diffusion of hydrogen and magnesium from the p-type semiconductor layer to the active layer. As a result, the initial degradation rate of the device when it is operated can be reduced, as compared to conventional nitride compound semiconductor light-emitting devices.

The present invention will be described in detail with reference to the accompanying drawings.

### First Embodiment

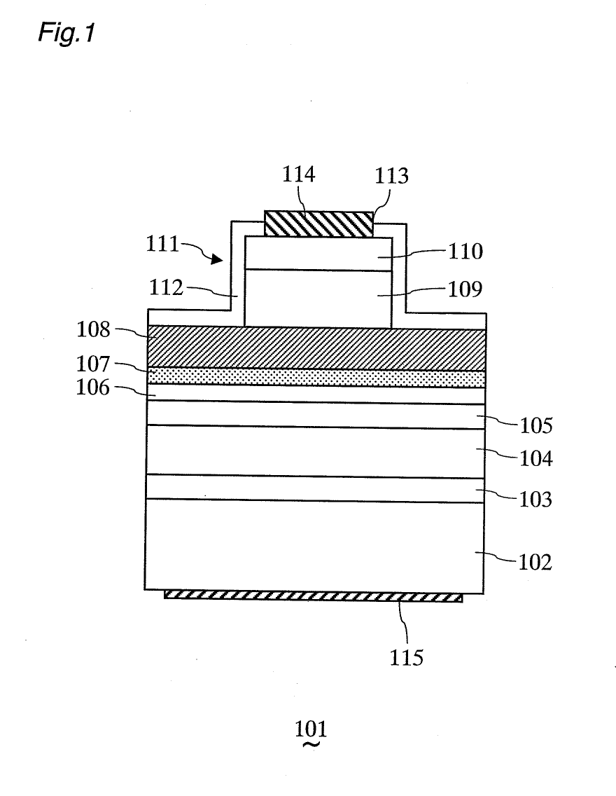

FIG. 1 is a cross-sectional view of a Group III-V nitride compound semiconductor laser device according to a first embodiment of the present invention.

As shown in FIG. 1, a semiconductor laser device 101 has a structure in which the following layers are sequentially laminated to one another over the top surface of a substrate 102 of gallium nitride (GaN): an n-type GaN layer 103, an n-type cladding layer 104, an n-type light guiding layer 105, a multiquantum well (MQW) active layer 106, an n-type diffusion blocking layer 107, a p-type electron barrier layer 108, a p-type cladding layer 109, and a p-type contact layer 110. The p-type cladding layer 109 and the p-type contact layer 110 together form a striped ridge 111. The ridge 111 is provided to define a waveguide region for constricting the current flowing within the active layer 106. It should be noted that the n-type GaN layer 103 and the n-type light guiding layer 105 may be omitted.

An insulating film 112 is formed on the p-type electron barrier layer 108 so as to cover the ridge 111. However, an opening 113 is formed in the portion of the insulating film 112 on the ridge 111, and a p-side electrode 114 is formed in contact with the p-type contact layer 110 through the opening 113. An n-side electrode 115, on the other hand, is formed on the back surface of the substrate 102, that is, the surface on which the n-type GaN layer 103 is not formed.

When a current is passed between the p-side electrode 114 and the n-side electrode 115 in the forward direction, electrons and holes are injected into the active layer 106, generating light. This light is confined and amplified within the waveguide and then emitted from the emitting end face side of the resonator as a laser beam.

There will now be described a method for manufacturing the semiconductor laser device 101.

General methods for growing a Group III-V nitride compound semiconductor layer in crystal form include metalorganic chemical vapor deposition (MOCVD), molecular beam epitaxy (MBE), and hydride vapor phase epitaxy (HVPE). Although the present embodiment uses MOCVD, any of these techniques can be used.

The present embodiment uses trimethyl gallium (TMG), trimethyl aluminum (TMA), and trimethyl indium (TMI) as raw materials for Group III compounds, and ammonia (NH₃) as a raw material for Group V compounds. Further, monosilane (SiH₄) and cyclopentadienyl magnesium (Cp₂Mg) are used as raw materials for n-type and p-type impurities, respectively. Still further, hydrogen (H₂) and nitrogen (N₂) are used as carrier gases for these raw materials.

The method for manufacturing the semiconductor laser device begins by providing the substrate 102 of gallium nitride (GaN) whose principal surface is a (0001)-plane. This substrate is miscut 0.1-1 degree toward the <1-100> or <11-20> direction, which allows the direction and density of the steps (on the surface) to be well defined thus allowing formation of a semiconductor layer having enhanced crystallinity and flatness. This results in a reduction in the point defect density and the stacking fault density of the p-type semiconductor (cladding) layer, thereby preventing diffusion of the residual hydrogen and magnesium in the layer. Then, after placing the substrate 102 within an MOCVD apparatus, the temperature within the apparatus is increased to 1000° C. while supplying ammonia (NH₃) gas. Then, trimethyl gallium (TMG) gas and monosilane (SiH₄) gas are supplied to form the n-type GaN layer 103 on the substrate 102. The thickness of the n-type GaN layer 103 may be, for example, approximately 1 μm.

Subsequently, trimethyl aluminum (TMA) gas is supplied to form the n-type cladding layer 104 of n-type aluminum gallium nitride (Al_{0.07}Ga_{0.93}N) on the n-type GaN layer 103. The thickness of the n-type cladding layer 104 may be, for example, approximately 1.0 μm.

Then, the supply of trimethyl aluminum (TMA) gas is stopped while maintaining the supply of the other gases. This forms the n-type light guiding layer 105 of n-type GaN on the n-type cladding layer 104. The thickness of the n-type light guiding layer 105 may be, for example, approximately 0.1 μm.

Then, the supply of trimethyl gallium (TMG) gas and monosilane (SiH₄) gas is stopped and the temperature within the apparatus is reduced to 700° C. After that, the multiquantum well active layer 106 of indium gallium nitride (InGaN) is formed on the n-type light guiding layer 105.

Specifically, trimethyl gallium (TMG) gas, trimethyl indium (TMI) gas, and ammonia (NH₃) gas are supplied to grow a well layer of In_{0.12}Ga_{0.88}N. Then, the supply of trimethyl indium (TMI) gas is stopped to form a barrier layer of GaN. The thicknesses of the well layer and the barrier layer may be, for example, approximately 3.5 nm and 7.0 nm, respectively. Pluralities of such well and barrier layers may be alternately formed to produce a layer stack, that is, the active layer 106. For example, the active layer 106 may include three pairs of well and barrier layers.

Then, the temperature is increased to 1000° C. again while supplying ammonia (NH₃) gas. After that, trimethyl gallium (TMG) gas, trimethyl aluminum (TMA) gas, and monosilane (SiH₄) gas are supplied to form the n-type diffusion blocking layer 107 of n-type Al_{0.03}Ga_{0.97}N on the active layer 106. The n-type diffusion blocking layer 107 may have a thickness of, e.g., 50 nm and a doping concentration of, e.g., 1×10¹⁸ cm⁻³.

Then, after stopping the supply of monosilane (SiH₄) gas, cyclopentadienyl magnesium (Cp₂Mg) gas is supplied to sequentially form the p-type electron barrier layer 108 of p-type Al_{0.2}Ga_{0.8}N and the p-type cladding layer 109 of p-type Al_{0.07}Ga_{0.93}N over the n-type diffusion blocking layer 107. The thicknesses of the p-type electron barrier layer 108 and the p-type cladding layer 109 may be, for example, approximately 0.02 μm and 0.4 μm, respectively.

Then, the supply of trimethyl aluminum (TMA) gas is stopped to form the p-type contact layer 110 of p-type GaN on the p-type cladding layer 109. The thickness of the p-type contact layer 110 may be, for example, approximately 0.1 μm.

After forming the p-type contact layer 110, the supply of trimethyl gallium (TMG) gas and cyclopentadienyl magnesium (Cp₂Mg) gas is stopped and the temperature is reduced to room temperature.

After completion of the above process, the ridge 111 is formed by a lithographic technique. Specifically, a resist is coated onto the entire surface and processed into a predetermined pattern. Then, the p-type contact layer 110 and the p-type cladding layer 109 are etched by reactive ion etching (RIE) using the above resist pattern as a mask, forming the ridge 111. This RIE process may use a chlorine-based gas as the etching gas, for example.

Then, the insulating film 112 is formed on the p-type electron barrier layer 108 so as to cover the ridge 111. Then, the opening 113 is formed in the portion of the insulating film 112 on the ridge 111 by a lift-off technique. Specifically, first, the insulating film 112 is formed over the entire surface including the above resist pattern by chemical vapor deposition (CVD), vacuum deposition, or sputtering. The insulating film 112 may be, for example, an SiO₂ film having a thickness of approximately 0.2 μm. Then, the resist pattern and the portion of the insulating film 112 on the resist pattern are removed to form the opening 113 above the ridge 111.

Then, a platinum (Pt) film and a gold (Au) film are formed over the entire surface by vacuum deposition, etc. After that, unwanted portions of these films are removed by a lithographic technique, leaving at least the portions of the films in the opening 113. This forms the p-side electrode 114 in the opening 113 such that the electrode is in ohmic contact with the p-type contact layer 110.

Then, a titanium (Ti) film, a platinum (Pt) film, and a gold (Au) film are sequentially formed over the entire back surface of the substrate 102 by vacuum deposition, etc. After that, an alloy process is applied to form the n-type electrode 115 functioning as an ohmic electrode.

After completion of the above process, the substrate 102 is processed into a bar or rod shape by cleavage, etc., forming both end faces (not shown) of the resonator. Then, after applying an appropriate coating to these end faces, the bar-shaped substrate 102 is processed into a chip by cleavage, etc., thus producing the semiconductor laser device 101.

Since the above manufacturing method uses organic metals, ammonia, and hydrogen as raw materials, the nitride compound semiconductor layers contain hydrogen. Especially, the p-type semiconductor layers contain more hydrogen than the n-type semiconductor layers, since magnesium used as a dopant combines with hydrogen in the p-type semiconductor layers. Generally, the amount of magnesium doped in the p-type semiconductor layers is 1×10¹⁸ cm⁻³ or more, and hence the amount of residual hydrogen in these layers is approximately equal to or less than this amount.

The residual hydrogen contained in the semiconductor layers, together with defects, degrades the characteristics and useful life of the semiconductor laser device. This is because the residual hydrogen diffuses into the active layer and degrades its characteristics. Especially, as described above, the p-type semiconductor layers contain more hydrogen than the n-type semiconductor layers, since the p-type semiconductor layers contain magnesium as a dopant, which combines with hydrogen. This means that preventing diffusion of hydrogen and magnesium from the p-type semiconductor layer to the active layer is effective in reducing the initial degradation rate of the semiconductor laser device.

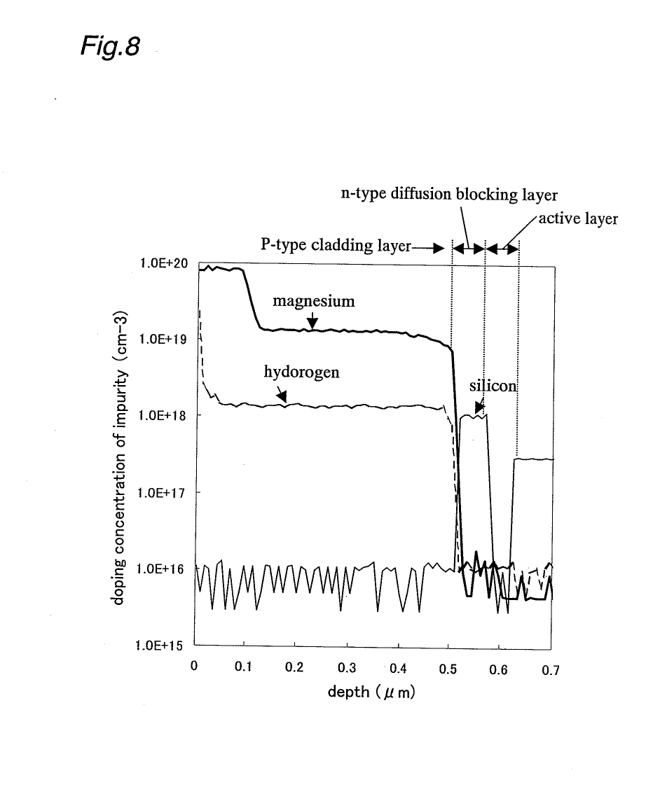

Thus, according to the present embodiment, an n-type diffusion blocking layer is provided between the active layer and the p-type semiconductor layer to prevent diffusion of magnesium and hydrogen from the p-type semiconductor layer to the active layer. Since the residual hydrogen in the p-type semiconductor layer is present in the form of H⁺, it is readily trapped by electrons in the n-type diffusion blocking layer and therefore does not reach the active layer. FIG. 8 shows the concentration profiles of magnesium, hydrogen, and silicon in the semiconductor laser device of the present embodiment as a function of depth. As shown, the n-type diffusion blocking layer prevents diffusion of hydrogen and magnesium from the p-type semiconductor layer to the active layer. This allows the semiconductor laser device to have a low initial degradation rate, which results in high reliability and an extended life.

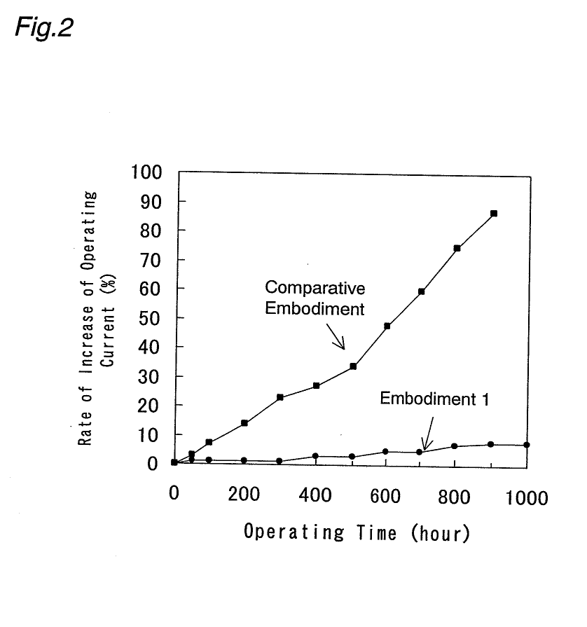

FIG. 2 shows results of testing the operation of the semiconductor laser device of the present embodiment. It should be noted that FIG. 2 also shows test results of a comparative semiconductor laser device which differs from the semiconductor laser device of the present embodiment in that it includes a 50 nm thick undoped Al_{0.03}Ga_{0.97}N layer instead of the n-type diffusion blocking layer. Except for this feature, the comparative semiconductor laser device was manufactured in the same manner as described above.

In these tests, the temperature was set at 80° C. and the semiconductor laser devices were operated so as to deliver an optical output power of 80 mW. In FIG. 2, the horizontal axis represents the operating time or the time during which power was applied to the semiconductor laser devices. In the figure, the vertical axis represents the rate of increase of the operating current, that is, the percentage increase in the operating current of the semiconductor laser devices relative to the initial operating current level.

As shown in FIG. 2, the comparative semiconductor laser device exhibited more than a 10% increase in operating current 200 hours after the start of its operation. Therefore, this semiconductor laser device does not satisfy practical characteristic requirements. The semiconductor laser device of the present embodiment, on the other hand, exhibited an increase in operating current of only less than 10% even 1000 hours after the start of its operation. This means that providing an n-type diffusion blocking layer between the active layer and the p-type semiconductor cladding layer allows the semiconductor laser device to have a low initial degradation rate and an extended life.

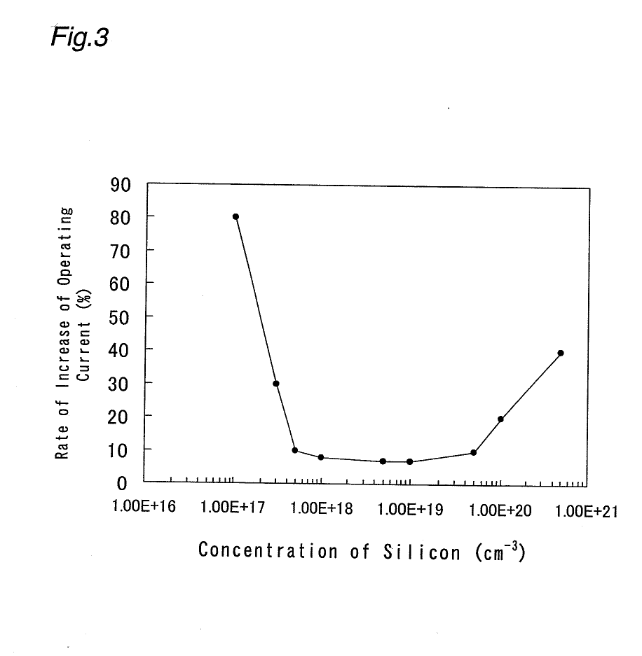

FIG. 3 shows results of testing the operation of the semiconductor laser device of the present embodiment, in which the doping concentration of the impurity in the diffusion blocking layer was varied. It should be noted that the thickness of the n-type diffusion blocking layer was 50 nm.

In FIG. 3, the horizontal axis represents the doping concentration of silicon as the impurity in the diffusion blocking layer. The doping concentration was varied from 1×10¹⁷ cm⁻³ to 5×10²⁰ cm⁻³. Further, the vertical axis represents the percentage increase in the operating current 1000 hours after the start of the operation. It should be noted that in this test the temperature was set at 80° C. and the semiconductor laser devices were operated so as to deliver an optical output power of 80 mW.

As shown in FIG. 3, when the doping concentration of silicon in the diffusion blocking layer was lower than 5×10¹⁷ cm⁻³, the rate of increase in the operating current was high, indicating a high degree of degradation. The reason for this is believed to be that the diffusion blocking layer was not able to effectively prevent diffusion of magnesium and hydrogen from the p-type semiconductor layer to the active layer since it contained only a low n-type impurity concentration. Further, the rate of increase in the operating current was also high when the doping concentration of silicon in the diffusion blocking layer exceeded 5×10¹⁹ cm⁻³. This is believed to be because the degradation in the crystallinity of the n-type AlGaN layer (i.e., the diffusion blocking layer) increased degradation of the semiconductor laser device.

When the doping concentration of silicon in the diffusion blocking layer was between 5×10¹⁷ cm⁻³ and 5×10¹⁹ cm⁻³, the rate of increase in the operating current was 10% or less, as shown in FIG. 3. Especially, when the doping concentration was between 1×10¹⁸ cm⁻³ and 2×10¹⁹ cm⁻³, the rate of increase in the operating current is reduced to a low level. That is, if the doping concentration of the diffusion blocking layer is within this range, the layer can effectively prevent diffusion of magnesium and hydrogen from the p-type semiconductor layer to the active layer, thereby allowing the semiconductor laser device to have a low initial degradation rate and an extended life.

It should be noted that instead of silicon, selenium or sulfur may be used as the n-type impurity. Also in such a case, the doping concentration is preferably between 5×10¹⁷ cm⁻³ and 5×10¹⁹ cm⁻³, more preferably between 1×10¹⁸ cm⁻³ and 2×10¹⁹ cm⁻³.

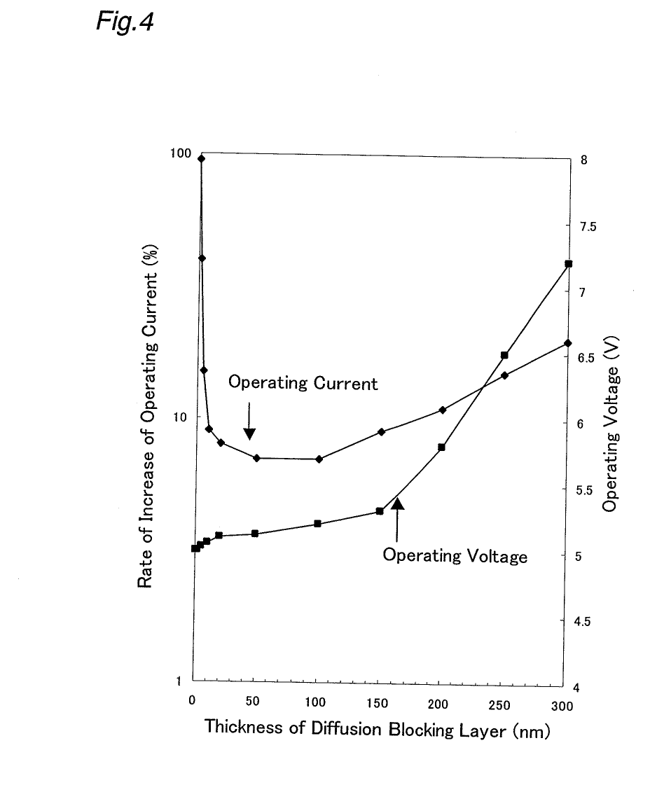

FIG. 4 shows results of testing the operation of the semiconductor laser device of the present embodiment, in which the thickness of the n-type AlGaN diffusion blocking layer was varied. In the figure, the horizontal axis represents the thickness of the diffusion blocking layer. The thickness of the diffusion blocking layer was varied from 0 nm to 300 nm. Further, the two vertical axes represent the percentage increase in the operating current and the operating voltage, respectively, 1000 hours after the start of the operation of the device. It should be noted that in this test the temperature was set at 80° C. and the semiconductor laser device was operated so as to deliver an optical output power of 80 mW. Further, the doping concentration of silicon as the n-type impurity in the diffusion blocking layer was 1×10¹⁸ cm⁻³.

As shown in FIG. 4, when the thickness of the diffusion blocking layer was smaller than 5 nm, the rate of increase in the operating current was high, indicating a high degree of degradation. The reason for this is believed to be that the diffusion blocking layer was not able to effectively prevent diffusion of magnesium and hydrogen from the p-type semiconductor layer to the active layer since it contained only a low n-type impurity concentration. On the other hand, when the thickness of the diffusion blocking layer was 5 nm or more, the layer reduced the rate of increase in the operating current, that is, it effectively prevented diffusion of magnesium and hydrogen from the p-type semiconductor layer to the active layer.

However, the thicker the diffusion blocking layer, the higher the operating voltage. The reason for this is that when the n-type diffusion blocking layer is thick, the PN junction assumes a “remote junction state,” resulting in an increased potential barrier. Specifically, when the thickness of the n-type diffusion blocking layer exceeded approximately 200 nm, the operating voltage of the semiconductor laser device exceeded 6 V, which is not desirable since such a semiconductor laser device exhibits increased power consumption when applied to an optical disk. Further, the thicker the n-type diffusion blocking layer, the lower the carrier injection efficiency into the active layer, resulting in degraded laser characteristics.

Therefore, the thickness of the diffusion blocking layer is preferably between 5 nm and 200 nm, more preferably between 10 nm and 150 nm, most preferably between 50 nm and 100 nm in order to effectively reduce the increase in the operating current.

Thus, the n-type diffusion blocking layer provided between the active layer and the p-type cladding layer can prevent diffusion of magnesium and hydrogen from the p-type cladding layer to the active layer, thereby allowing the semiconductor laser device to have a low initial degradation rate and an extended life. In this case, the doping concentration of the n-type impurity in the n-type diffusion blocking layer is preferably between 5×10¹⁷ cm⁻³ and 5×10¹⁹ cm⁻³. Further, the thickness of the n-type diffusion blocking layer is preferably between 5 nm and 200 nm.

It should be noted that according to the present embodiment a p-type electron barrier layer is provided between the n-type diffusion blocking layer and the p-type cladding layer such that the p-type electron barrier layer is in contact with the n-type diffusion blocking layer. According to the present invention, this p-type electron barrier layer need not necessarily be provided. However, the p-type electron barrier layer helps effectively prevent diffusion of magnesium and hydrogen from the p-type cladding layer to the active layer.

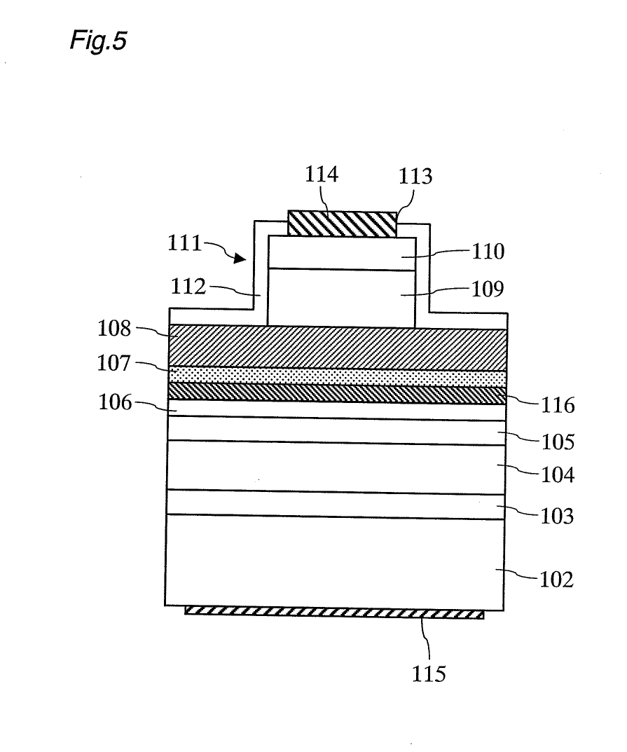

Further, according to the present embodiment, an undoped guiding layer 116 may be provided between the active layer 106 and the n-type diffusion blocking layer 107, as shown in FIG. 5. It should be noted that in FIG. 5, components common to FIG. 1 are denoted by the same reference numerals.

The guiding layer 116 may be a 30 nm thick undoped In_{0.02}Ga_{0.98}N layer. The guiding layer 116 enhances the light confinement characteristics, thereby providing a desired far field pattern (FFP).

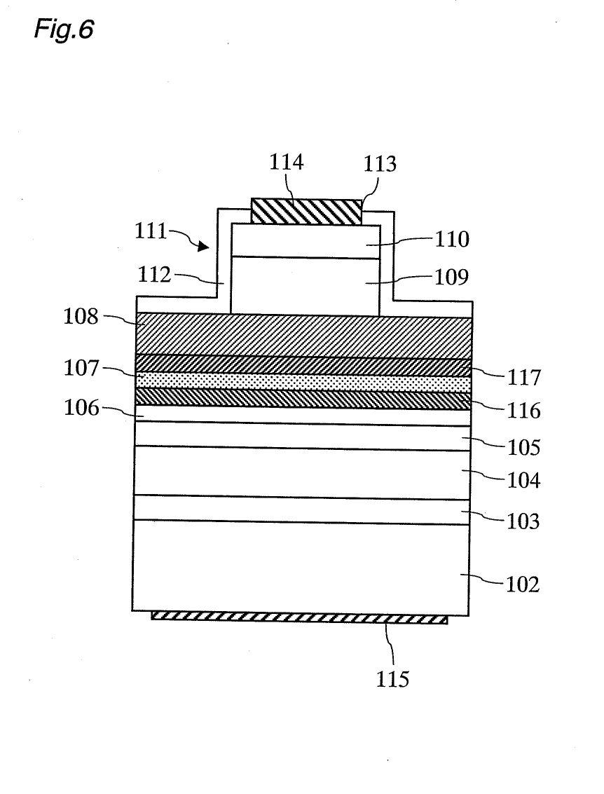

Further, according to the present embodiment, an undoped GaN layer 117 may be provided between the n-type diffusion blocking layer 107 and the p-type electron barrier layer 108, as shown in FIG. 6. It should be noted that in FIG. 6, components common to FIG. 1 or 5 are denoted by the same reference numerals.

The thickness of the GaN layer 117 may be, for example, approximately 5 nm. When the GaN layer 117 is provided between the n-type diffusion blocking layer 107 and the p-type electron barrier layer 108, the conduction band energy difference (ΔEc) between the p-type electron barrier layer 108 and the GaN layer 117 helps block overflow of electrons injected into the active layer 106, thereby allowing the semiconductor laser device to have good laser characteristics even when it delivers high output power at high temperature. It should be noted that an undoped In_{0.02}Ga_{0.98}N layer may be used instead of the undoped GaN layer. In this case, a larger conduction band energy difference (ΔEc) can be achieved, allowing further reduction of electron overflow.

### Second Embodiment

The n-type diffusion blocking layer of the first embodiment is made up of a single layer, namely, an n-type AlGaN layer. On the other hand, a second embodiment of the present invention uses an n-type diffusion blocking layer made up of a plurality layers that are made of a compound represented by formula (2) below.

InₓAl_{y}Ga_{1-x-y}N(x≧0, y≧0, and (x+y)<1) (2)

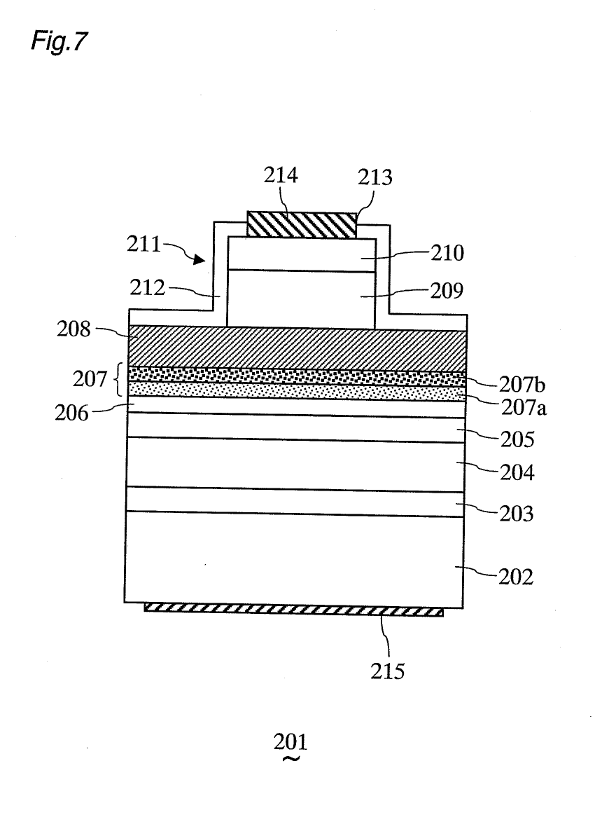

FIG. 7 is a cross-sectional view of a Group III-V nitride compound semiconductor laser device according to the present embodiment.

As shown in FIG. 7, a semiconductor laser device 201 has a structure in which the following layers are sequentially laminated to one another over the top surface of a substrate 202 of gallium nitride (GaN): an n-type GaN layer 203, an n-type cladding layer 204, an n-type light guiding layer 205, a multiquantum well (MQW) active layer 206, an n-type diffusion blocking layer 207, a p-type electron barrier layer 208, a p-type cladding layer 209, and a p-type contact layer 210. The p-type cladding layer 209 and the p-type contact layer 210 together form a striped ridge 211. The ridge 211 is provided to define a waveguide region for constricting the current flowing within the active layer 206. It should be noted that the n-type GaN layer 203 and the n-type light guiding layer 205 may be omitted.

An insulating film 212 is formed on the p-type electron barrier layer 208 so as to cover the ridge 211. However, an opening 213 is formed in the portion of the insulating film 212 on the ridge 211, and a p-side electrode 214 is formed in contact with the p-type contact layer 210 through the opening 213. An n-side electrode 215, on the other hand, is formed on the back surface of the substrate 202, that is, the surface on which the n-type GaN layer 203 is not formed.

When a current is passed between the p-side electrode 214 and the n-side electrode 215 in the forward direction, electrons and holes are injected into the active layer 206 to generate light. This light is confined and amplified within the waveguide and then emitted from the emitting end face side of the resonator as a laser beam.

The semiconductor laser device 201 may be manufactured in the same manner as the semiconductor laser device 101 of the first embodiment except that the n-type diffusion blocking layer 207 is made up of an n-type AlGaN layer 207a and an n-type InGaN layer 207b. These layers may be formed, for example, by metalorganic chemical vapor deposition (MOCVD).

Specifically, the n-type AlGaN layer 207a may be formed, for example, by increasing the temperature to 1000° C. while supplying ammonia (NH₃) gas, and then supplying trimethyl gallium (TMG) gas, trimethyl aluminum (TMA) gas, and monosilane (SiH₄) gas. In this case, the composition ratio of the n-type AlGaN layer 207a is such that the ratio of aluminum to gallium is 3:97.

The n-type InGaN layer 207b may be formed, for example, by reducing the temperature to 700° C. and then supplying trimethyl gallium (TMG) gas, trimethyl indium (TMI) gas, and ammonia (NH₃) gas. In this case, the composition ratio of the n-type InGaN layer 207b is such that the ratio of indium to gallium is 2:98.

Examples of n-type impurities that may be doped in the n-type AlGaN layer 207a and the n-type InGaN layer 207b include silicon (Si), selenium (Se), and sulfur (S). The doping concentrations of the n-type AlGaN layer 207a and the n-type InGaN layer 207b are preferably set such that the entire n-type diffusion blocking layer 207 made up of these layers has a doping concentration of 5×10¹⁷ cm⁻³ or more. If the doping concentration of the n-type diffusion blocking layer 207 is lower than 5×10¹⁷ cm⁻³, the layer cannot effectively prevent diffusion of magnesium and hydrogen from the p-type cladding layer 209 to the active layer 206 since it contains only a low n-type impurity concentration. This increases the operating current and hence degradation of the semiconductor laser device. The upper limit of the doping concentration, on the other hand, may be determined by taking into account the crystallinity of the n-type AlGaN layer 207a and the n-type InGaN layer 207b. Specifically, the doping concentrations of the n-type AlGaN layer 207a and the n-type InGaN layer 207b are preferably 5×10¹⁹ cm⁻³ or less.

The thickness of the n-type diffusion blocking layer 207, that is, the combined thickness of the n-type AlGaN layer 207a and the n-type InGaN layer 207b, is preferably between 5 nm and 200 nm, more preferably between 10 nm and 150 nm, most preferably between 50 nm and 100 nm. If the thickness of the n-type diffusion blocking layer 207 is smaller than 5 nm, the rate of increase in the operating current of the semiconductor laser device increases, resulting in increased degradation of the device. If the thickness of the n-type diffusion blocking layer 207 is 5 nm or more, the layer can reduce the rate of increase in the operating current. However, the larger the thickness of the n-type diffusion blocking layer 207, the higher the operating voltage. Therefore, the thickness of the n-type diffusion blocking layer 207 is preferably 200 nm or less.

Thus, according to the present embodiment, as in the first embodiment, the n-type diffusion blocking layer provided between the active layer and the p-type cladding layer can prevent diffusion of magnesium and hydrogen from the p-type cladding layer to the active layer, thereby allowing the semiconductor laser device to have a low initial degradation rate and an extended life.

It should be noted that although the present embodiment uses an n-type diffusion blocking layer (207) made up of two layers, namely, the n-type AlGaN layer 207a and the n-type InGaN layer 207b, the present invention is not limited to this particular n-type diffusion blocking layer. The present invention may employ an n-type diffusion blocking layer made up of any plurality of layers, even three or more layers, that are made of a compound represented by formula (2) above.

Further, although each of the layers constituting the n-type diffusion blocking layer 207 of the present embodiment is doped with an n-type impurity, the present invention is not limited to this particular arrangement. An n-type impurity may be doped in only one of the layers constituting the n-type diffusion blocking layer. For example, the n-type diffusion blocking layer may be made up of an n-type AlGaN layer and an undoped InGaN layer. Even such an n-type diffusion blocking layer can prevent diffusion of magnesium and hydrogen from the p-type cladding layer to the active layer, thereby allowing the semiconductor laser device to have a lower initial degradation rate and a longer operating life than conventional semiconductor laser devices.

It should be noted that according to the present embodiment a p-type electron barrier layer is provided between the n-type diffusion blocking layer and the p-type cladding layer such that the p-type electron barrier layer is in contact with the n-type diffusion blocking layer. According to the present invention, this electron barrier layer can be omitted. However, the p-type electron barrier layer helps effectively prevent diffusion of magnesium and hydrogen from the p-type cladding layer to the active layer.

When a p-type electron barrier layer is provided between the n-type diffusion blocking layer and the p-type cladding layer, an undoped GaN layer is preferably additionally provided between the n-type diffusion blocking layer and the p-type electron barrier layer. The thickness of the GaN layer may be, for example, approximately 5 nm. With such an arrangement, the conduction band energy difference (ΔEc) between the p-type electron barrier layer and the GaN layer helps block overflow of electrons injected into the active layer, thereby allowing the semiconductor laser device to have good laser characteristics even when it delivers high output power at high temperature. It should be noted that an undoped In_{0.02}Ga_{0.98}N layer may be used instead of the undoped GaN layer. In this case, a larger conduction band energy difference (ΔEc) can be achieved, allowing further reduction of electron overflow.

Further, according to the present embodiment, an undoped guiding layer may be provided between the active layer and the n-type diffusion blocking layer, as in the first embodiment. The guiding layer may be a 30 nm thick undoped In_{0.02}Ga_{0.98}N layer. The guiding layer enhances the light confinement characteristics, thereby providing a desired far field pattern (FFP).

It should be understood that the present invention is not limited to the embodiments described above, and various alterations may be made thereto without departing from the spirit and scope of the invention.

For example, although the above preferred embodiments have been described with reference to semiconductor laser devices, the present invention is not limited to such devices. The present invention can be applied to other types of semiconductor light-emitting devices such as light-emitting diodes.

The features and advantages of the present invention may be summarized as follows.

According to the present invention, an n-type diffusion blocking layer is provided between the active layer and the p-type cladding layer to prevent diffusion of magnesium and hydrogen from the p-type cladding layer to the active layer, thereby allowing the semiconductor light-emitting device to have a low initial degradation rate and an extended life.

Obviously many modifications and variations of the present invention are possible in the light of the above teachings. It is therefore to be understood that within the scope of the appended claims the invention may be practiced otherwise than as specifically described.

The entire disclosure of a Japanese Patent Application No. 2006-262845, filed on Sep. 27, 2006 and a Japanese Patent Application No. 2007-217511, filed on Aug. 23, 2007 including specification, claims, drawings and summary, on which the Convention priority of the present application is based, are incorporated herein by reference in its entirety.

1-2. (canceled)

3. The semiconductor light-emitting device according to claim 1, wherein:
said n-type diffusion blocking layer of includes a plurality of layers; and
at least one of said plurality of layers contains a dopant impurity producing n-type conductivity.

4. The semiconductor light-emitting device according to claim 3, wherein concentration of said dopant impurity is at least 5×10¹⁷ cm⁻³, in all layers of said n-type diffusion blocking layer.

5. The semiconductor light-emitting device according to claim 4, wherein concentration of said dopant impurity is 5×10¹⁹ cm⁻³ or less, in each layer of said n-type diffusion blocking layer.

6-10. (canceled)
